(19) United States
(12) Patent Application Publication
(10) Pub. No.: US 2008/0200327 A1
(43) Pub. Date: Aug. 21, 2008

(54) BARIUM TITANATE SINGLE CRYSTAL AND PREPARATION METHOD THEREOF

(76) Inventors: Wei-Hsing Tuan, Taipei (TW); Yung-Ching Huang, Linkou Township (TW)

Correspondence Address: SCHMEISER, OLSEN & WATTS, 22 CENTURY HILL DRIVE, SUITE 302, LATHAM, NY, 12110, US

(21) Appl. No.: 11/832,675

(22) Filed: Aug. 2, 2007

(30) Foreign Application Priority Data
Feb. 16, 2007 (TW) 096106300

(51) Int. Cl. C04B 35/515; C30B 1/02

(52) U.S. Cl. 501/137; 117/3; 117/7

(57) ABSTRACT

The present invention provides a method of producing the barium titanate solid solution single crystals. The crystalline phase of the single crystal is hexagonal. The method of the present invention, a small quantity of metal oxide is added and dissolved into the barium titanate to form a solid solution. The metal oxides are used as single crystal growth aid; and the barium titanate single crystal can be prepared by using a pressureless sintering process composing of one or two stages of heat treatments that require no special expensive equipments, and thus the method can be used for the mass production of the single crystals.

### FIELD OF THE INVENTION

The present invention relates to a barium titanate solid solution single crystal and a preparation method thereof, and more particularly to a hexagonal phase barium titanate single crystal that can be prepared by adding and dissolving a small quantity of transition metal oxide into barium titanate, and prepared by using a pressureless sintering process at normal atmospheric pressure.

Since barium titanate polycrystalline ceramic has an excellent ferroelectric property, therefore it is used widely as passive components and communication components. However, the grain boundary often presents in a polycrystalline material, and those single crystals do not have any grain boundary, and thus their properties are the best theoretically. The ferroelectric properties of barium titanate single crystals are better than those of the barium titanate polycrystals. Since there is no grain boundary, the single crystals have a light transmitting capability. With a special refractive nature, the single crystals can be applied in the area of optical communications and thus they have a high potential for both electrical and optical applications.

### BACKGROUND OF THE INVENTION

Barium titanate is a ferroelectric material with high permittivity. The phase of barium titanate at room temperature is a tetragonal phase, it then transforms to cubic phase at 130° C., and then transforms to hexagonal phase above 1460° C. The preparation of tetragonal barium titanate single crystal can attract a lot of attention. However, the preparation of hexagonal phase barium titanate attracted much less attention. Apart from the ferroelectric performance of the barium titanate single crystal, due to the absence of grain boundary in single crystal, the barium titanate single crystal is also a potential material for optical applications. For example, the barium titanate is an excellent photorefractive material having the features of a highly self-pumped phase conjugator and a two-beam coupling effect. Various optical conversional tools can be made by using the barium titanate single crystals, thus the barium titanate single crystals are used widely in many areas, such as in optical information storage, interferometer, optical computation, holographic memory, conjugate optics and many other areas, which indicates that the barium titanate single crystals have excellent industrial prospects. However, the growth of the barium titanate single crystals is very difficult. Although a large number of researchers are devoted to the growth of the barium titanate single crystals, not too many of them have succeeded. As a result, the price of the barium titanate single crystals remains very high (over 300 US dollars for a piece of barium titanate single crystal with a volume of 5×5×5 mm³). Until now, only the tetragonal barium titanate single crystal is available, and the hexagonal barium titanate single crystal is still not available. At present, the conventional methods of growing barium titanate single crystals rely on the expensive instruments, expensive equipments and complicated manufacturing procedures to grow large single crystals. One of the conventional methods, utilizes the melting properties of the materials, such as a top-seeded solution growth (TSSG) method is used for achieving the growth of the liquid-state single crystals, and this method puts a ceramic material into a crucible and heats the ceramic material till it melts, and then puts a small single crystal at the top of the melted ceramic material as a crystal seed, and pulls the small seed crystal by the Czochralski method. The crystal seed is in contact with the surface of the melted ceramic liquid, and the crystal seed is rotated and pulled, such that the crystal seed starts growing into single crystals. But, this method has the shortcomings of requiring an accurate temperature control and complicated production equipments, providing a slow growth rate, and incurring a high manufacturing cost.

In addition, another conventional method called laser-heated pedestal growth (LHPG) is used for growing the single crystals, and this method has following advantages: The laser light source can narrow the range of heated light beams, and thus only a small portion of the raw material is heated. As a result, the contamination from the crucible can be reduced. Furthermore, the laser light source has a high temperature gradient to induce a quick crystal growth, it also comprises a high power to melt the materials with a high melting point or to grow the non-eutectic materials. However, the high temperature gradient of the laser light source also comes along with some drawbacks, such as easy breaking crystal grains when the diameter increases, and expensive and complicated equipments are required.

In another conventional method of growing barium titanate single crystals, several elements with high concentration gradient are mixed into a pure barium titanate ceramic green part or it requires a temperature gradient at the sintering process in order to produce the single crystal. Therefore, this method must adopt the two-stages of heat treatment for preparing the crystal seed in order to produce the barium titanate single crystals.

To summarize the descriptions above, the conventional methods of growing tetragonal phase barium titanate single crystals still have their limitations and disadvantages, and the major drawbacks include the complicated manufacturing process, the expensive instruments and equipments, and the high production cost.

Therefore, it is an important object of the present invention to find a way of producing the barium titanate single crystals by a simple method to improve the yield rate and to reduce the cost of the barium titanate single crystals. Furthermore, similar to the tetragonal phase, the hexagonal phase is also not a symmetric crystal. The dipoles composing of positive and negative ions are existed. The potential of using hexagonal phase barium titanate single crystal for ferroelectric and optical applications is also high.

### SUMMARY OF THE INVENTION

In view of the shortcomings of the prior art, the inventors of the present invention based on years of experience in the related fields. Many experiments have been conducted, and finally developed a barium titanate single crystal and a growing method to simplify the manufacturing procedure, and to improve the yield rate and to reduce production cost.

Therefore, it is a primary objective of the present invention to provide a barium titanate single crystal. The barium titanate single crystal is primarily made of a novel barium titanate ceramic material with a small quantity of metal oxides to grow into a form of large barium titanate single crystal. The raw material for the preparation of barium titanate single crystal is composed of pure barium titanate ceramic powder and at least one metal oxide powder distributed uniformly in the ceramic powder.

The present invention discloses a chemical composition for the preparation of barium titanate single crystal. Apart from the starting barium titanate, a metal oxide is also added. The initial content of the metal oxide varies preferably from 0.01 wt % to 5 wt %, based on the total weight of the barium titanate ceramic powder, and more preferably 0.01 wt % to 2 wt %, and most preferably 0.05 wt % to 0.8 wt %. The metal oxide used as a single crystal growth aid in the present invention is a transition metal oxide, it includes but not being limited to, nickel oxide, iron oxide or their mixtures. The barium titanate ceramic powder is mixed with the solid solution metal oxide and sintered at a high temperature and in a normal atmospheric pressure to produce a large barium titanate single crystal.

The present invention also discloses a method of preparing the single crystal, particularly a method of preparing a barium titanate single crystal. The method comprises melting of a transition metal salt into an appropriate solvent; mixing the solution into a dielectric ceramic powder to form a slurry, calcining the mixed powder at an appropriate high temperature to prepare a specimen; thermally decomposing the transition metal salt into a transition metal oxide; and resulting a uniform mixing of metal oxide.

The solvent used for melting the transition metal salt in accordance with the preferred example of the present invention comprises: an alcohol, such as ethanol, methanol and isopropanol. The transition metal salt used in the method of the present invention further comprises but it not limits to, a nickel salt or an iron salt. The foregoing mixed slurry is dried to powder by removing the solvent with an appropriate method, and the dried powder can be used for the later heating and sintering processes. The method of removing the solvent can be a centrifugal drying method, a direct bake-to-dry method or a rotary drying method. The sintering process refers to the process comprising a temperature rise to 1300° C. and a temperature holding of an hour, and a cooling. The sintered powder can be grounded and sieved first to give a powder and then pressed to form a specimen used for a later pressureless sintering process.

In the pressureless sintering method, a high-temperature heat treatment is carried out at normal atmospheric pressure to produce the specimen, wherein the sintering temperature varies from 1350° C. to 1500° C., and the sintering time from several minutes to several hours. This method can grow a single crystal of the size of 10×5×5 mm³ or larger.

The pressureless sintering method can be a one-stage heat treatment or a two-stages heat treatment. For one-stage heat treatment, the sintering process is performed at normal atmospheric pressure, and the sintering conditions comprises a temperature risen to a temperature range of 1350° C. to 1500° C., a constant sintering temperature maintaining for several minutes to several hours, and a cooling process. For a two-stages heat treatment, the sintering process is also performed at a normal atmospheric pressure, and the sintering conditions comprise a temperature risen to a temperature range from 1400° C. to 1500° C., no constant temperature maintaining or a constant temperature maintaining for several minutes, and a cooling process to a temperature range from 1300° C. to 1400° C., a constant temperature maintaining for several minutes to several hours, and a cooling process. In the one-stage or two-stages heat treatment, the high-temperature holding time may vary from 1 minute to 10 hours.

The objectives, features and advantages of the present invention would become apparent from the following detailed description taken with the accompanying drawing.

### BRIEF DESCRIPTION OF THE DRAWINGS

The accompanying drawings are included to provide a further understanding of the present invention, and are incorporated in and constitute a part of this specification. The drawings illustrate embodiments of the invention and, together with the description, serve to explain the principles of the invention. In the drawings,

FIG. 1 shows two photos of barium titanate in accordance with the first embodiment of the present invention, wherein the barium titanate is made by a one-stage sintering method with (a) a sintering temperature of 1400° C. or (b) a sintering temperature of 1500° C.;

FIG. 2 shows the X-ray diffraction patterns of the pure and Ni-doped barium titanate specimens after sintering at 1400° C. for 2 hour. The upper figure shows the X-ray diffraction pattern of the barium titanate specimen used in the first embodiment. The lower figure shows the X-ray diffraction pattern of the 0.2 wt % Ni-doped barium titanate specimen in the second embodiment. Very large barium titanate grains are found in the specimen;

FIG. 3 shows three photos of barium titanate specimens added with a small amount of nickel oxide in accordance with the second embodiment of the present invention, wherein the barium titanate is made by a one-stage sintering method with (a) a nickel oxide content of 0.2 wt %, a sintering temperature of 1400° C. and a temperature holding time of 2 hours, or (b) a nickel oxide content of 0.2 wt %, a sintering temperature of 1500° C. and a temperature holding time of 2 hours, or (c) a nickel oxide content of 0.05 wt %, a sintering temperature of 1385° C., and a temperature holding time of 2 hours;

FIG. 4 shows the barium titanate single crystals obtained from the specimens shown in FIG. 3.

FIG. 5 shows two photos of barium titanate containing 0.35 wt % of iron oxide in accordance with the third preferred embodiment of the present invention, wherein the barium titanate is made by a one-stage sintering method with (a) a sintering temperature of 1410° C. or (b) a sintering temperature of 1500° C.;

FIG. 6 is a curve showing the temperature profile of a two-stage sintering method in accordance with the fourth preferred embodiment of the present invention;

FIG. 7 shows a photo of barium titanate containing 0.2 wt % of a nickel oxide in accordance with the fourth preferred embodiment of the present invention, wherein the second-stages sintering temperature is 1400° C.; and

FIG. 8 shows a photo of barium titanate containing 0.35 wt % of iron oxide and prepared by a two-stages sintering method in accordance with the fourth preferred embodiment of the present invention, wherein the second-stage sintering temperature is 1380° C.

### DETAILED DESCRIPTION OF THE PREFERRED EMBODIMENTS

In order to understand the objective, innovative features and performance of the present invention, four embodiments and their corresponding drawings are used to give detailed description of the present invention.

### First Embodiment

This embodiment is used as the basis for the comparison. According to a embodiment of the present invention, a barium titanate (BaTiO3>99%, manufactured by U.S. Ferro Company) powder and alcohol are put into a PE bottle, and zirconium oxide balls are used as grinding media for grinding the powder and alcohol into a slurry, wherein the particle size of pure barium titanate powder is 1 μm.

The liquid of the slurry is removed first by drying with a rotary evaporator then putting into an oven to dry at 100° C. for another 24 hours.

The dried powder are removed from the oven, ground by using mortar and pestle, sieved by using a 150-mesh sieve, and dry pressed at a pressure of 20 MPa to produce a cylindrical disc with a diameter of 1 cm or 1 inch.

The specimen is put into a high-temperature furnace and sintered in a normal atmospheric pressure, wherein the sintering conditions comprise a temperature heating up with a rate of 3° C./min, a sintering temperature of 1350˜1500° C., a constant temperature maintaining for 2 hours, and a cooling process with a rate of 3° C./min.

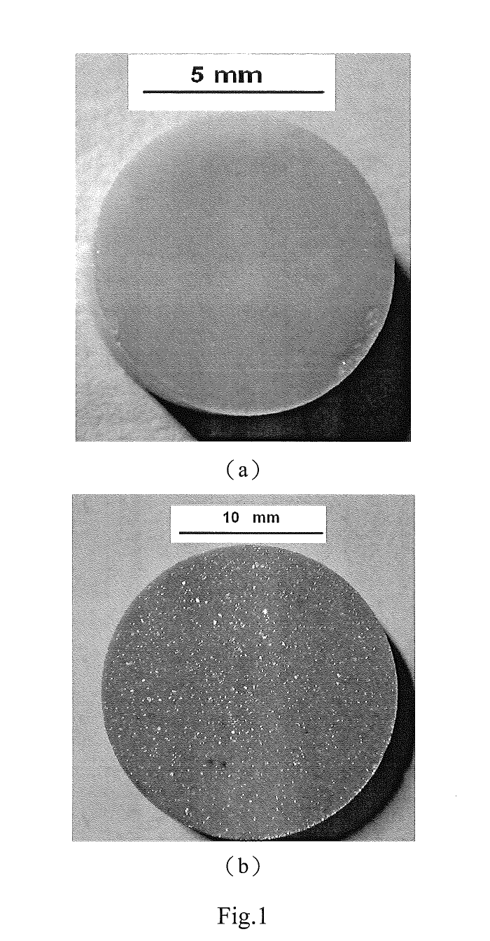

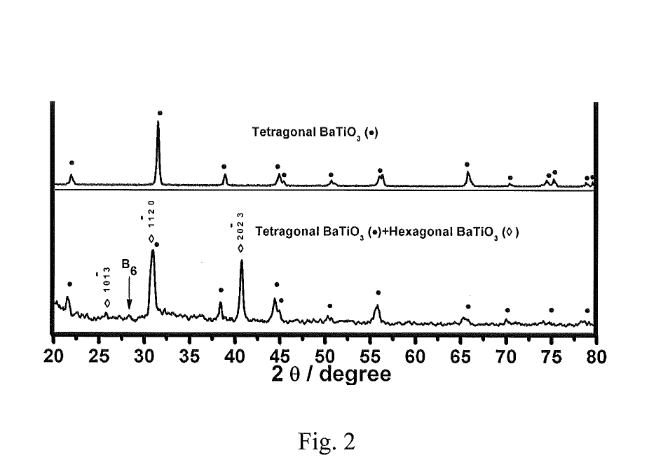

Referring to FIG. 1 for the surface of the pure barium titanate specimen, the crystal grains have the size of tens of micrometers and cannot be grown to mm-scale crystals after going through the high-temperature pressureless sintering process. The X-ray pattern for the barium titanate specimen shown in FIG. 1(a) is illustrated in FIG. 2. The specimen was sintered at 1400° C. of 2 hours. Only the tetragonal phase is found.

### Second Embodiment

In this embodiment, we can observe the effect of different proportions of transition metal oxides on the microstructure of the barium titanate. This embodiment adds a nickel oxide, a transition metal oxide, into barium titanate powder through the use of different proportions of nickel nitrate, and carrying out the heat treatment as follows:

The barium titanate powder (which is the same one adopted in the first embodiment) and nickel nitrate of different proportions are put into a PE bottle containing alcohol and mixed by the ball milling for 4 hours to form a slurry, wherein zirconium oxide balls are used as the grinding media.

The liquid of the slurry is removed firstly by drying with a rotary evaporator, then it is put into an oven to dry at 100° C. for another 24 hours.

The dried powder is removed from the oven, ground by using mortar and pestle, sieved by using a 150-mesh sieve, and sintered in an aluminum oxide crucible in normal atmospheric pressure, wherein the calcination conditions include a temperature heating up with a rate of 1° C./min, a constant temperature maintaining at 500° C. for one hour, a cooling process with a rate of 1° C./min, in such that the nickel nitrate in the powder is converted into nickel oxide, and the nickel oxide content after the calcination process is 0.05˜0.8 wt % of the total weight of the powder.

The dried powder is removed from the furnace and ground with mortar and pestle, sieved by using a 150-mesh sieve, and die pressed at a pressure of 20 MPa to produce a disc specimen with a diameter of 1 inch.

The specimen is put into a high-temperature furnace and sintered at normal atmospheric pressure, and the sintering conditions comprise a temperature heating up with a rate of 3° C. /min, a constant temperature maintaining at a temperature range of 1350˜1500° C., a constant temperature maintaining for 1 to 2 hours, and a cooling process with a rate of 3° C./min.

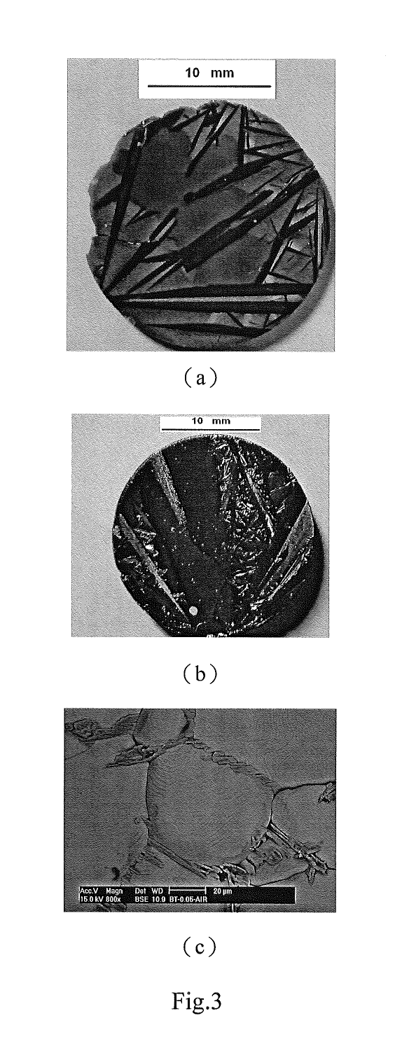

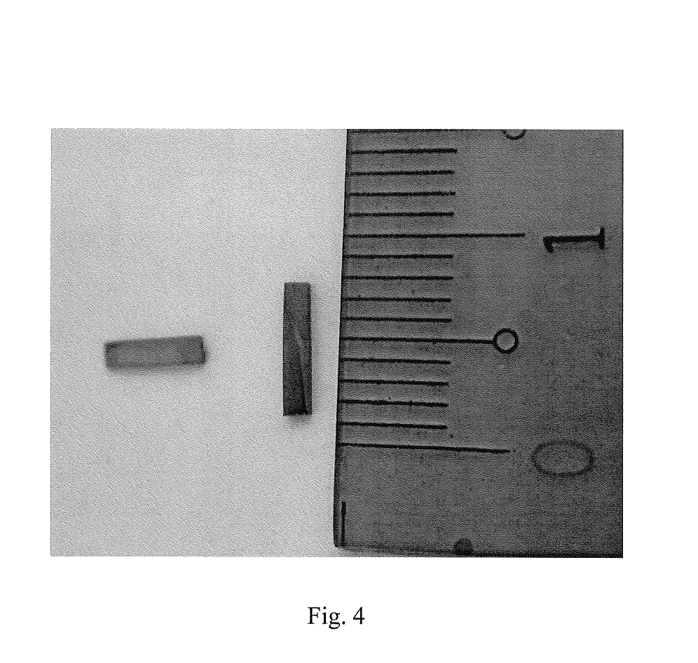

Refer to FIG. 2, the crystalline phases of the 0.2 wt % nickel oxide doped barium titanate specimen after sintering at 1400° C. for 2 hours are tetragonal and hexagonal. The grains with hexagonal phase tend to form anisotropic shape due to the growth rate of each crystalline plane is not the same. These hexagonal large grains can be seen in FIG. 3. After removing the large hexagonal grains from the specimens, hexagonal phase single crystal can be obtained. Typical single crystals are shown in FIG. 4. The present embodiment demonstrates that the hexagonal barium titanate can be obtained at a temperature lower than 1460° C., due to the addition of a transition metal oxide. Furthermore, the presence of the transition metal oxide enhances the grain growth of the barium titanate crystals.

Referring to FIG. 3(a) for the specimen containing 0.2 wt % nickel oxide, the large single crystals are formed by sintering a barium titanate specimen containing 0.2 wt % of nickel oxide at a sintering temperature of 1400° C., and the temperature is maintained constantly for 2 hours, and the single crystals can grow to large single crystals with a length equal to or greater than 10 mm. In FIG. 3(b), the sintering temperature is 1500° C., and the grains can grow to large single crystals with a length equal to or greater than 20 mm as shown in FIG. 3(b).

For the sintering conditions comprise of the sintering temperature at 1385° C. and a constant temperature maintaining for 2 hours, and the content of nickel oxide is 0.05 wt %, we can also observe large crystals formed in the barium titanate specimen as shown in FIG. 3(c).

### Third Embodiment

In this embodiment of the present invention, we can observe the effect of another metal oxide on the microstructure of barium titanate. This metal oxide is also added into the barium titanate powder before the sintering process. This preferred embodiment uses iron oxide as the metal oxide. Iron nitrate with different proportions is added and mixed with the barium titanate powder, and a heat treatment is performed as follows:

The barium titanate powder (which is the same one adopted in the aforementioned embodiment) and iron nitrate of an appropriate quantity are put into a PE bottle containing alcohol and are mixed by ball milling for 4 hours to form a slurry, wherein zirconium oxide balls are used as the grinding media.

The liquid of the slurry is removed firstly by drying with a rotary evaporator, then it is put into an oven to dry at 100° C. for another 24 hours for the drying process.

The dried powder is removed from the oven, ground by using mortar and pestle, sieved by using a 150-mesh sieve, and calcineded in an aluminum oxide crucible at normal atmospheric pressure, wherein the calcination conditions include a temperature heating up with rate of 1° C./min, a constant temperature maintaining at 500° C., and a constant temperature maintaining for an hour, a cooling process with a rate of 1° C./min, such that the iron nitrate in the powder is changed into the iron oxide, and the content of the iron oxide is 0.35 wt % of the total weight of the powder.

The dried powder is removed, and then grounded by using mortar and pestle, sieved by using a 150-mesh sieve, and die pressed at a pressure of 20 MPa to produce a disc specimen with a diameter of 1 inch.

The specimen is put into a high-temperature furnace and sintered in normal atmospheric pressure, and the sintering conditions include a temperature heating up with a rate of 3° C./min, a constant temperature maintaining at a temperature range of 1350˜1500° C., a constant temperature maintaining for 2 hours, and a cooling process with a rate of 3° C./min.

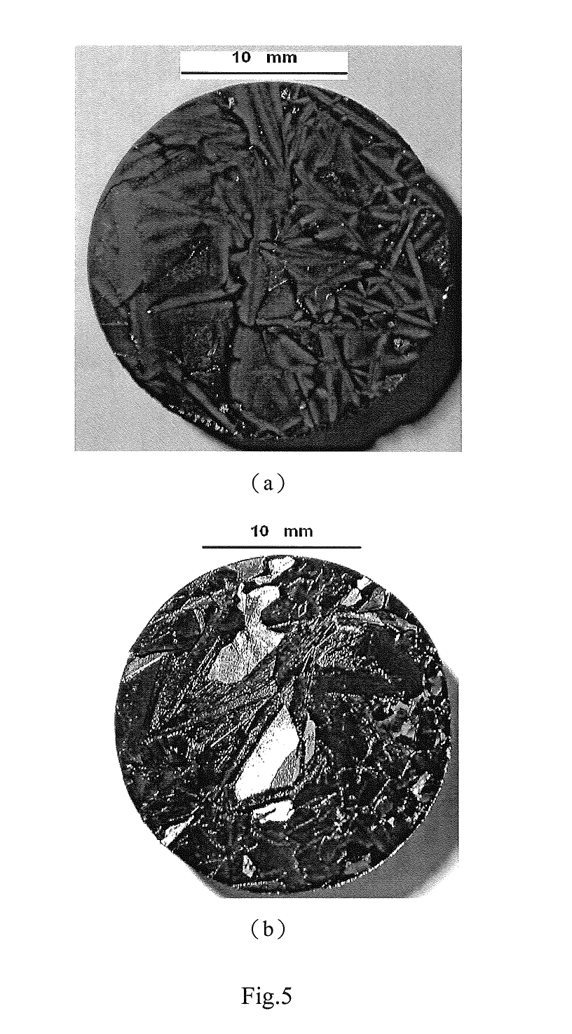

In FIG. 5, we can observe the surface of the specimens, wherein FIG. 5(a) shows a specimen sintered at a sintering temperature of 1410° C., and FIG. 5(b) shows a specimen sintered at a sintering temperature of 1500° C. Obviously, lots of large single crystals are formed in the whole barium titanate specimen.

### Fourth Embodiment

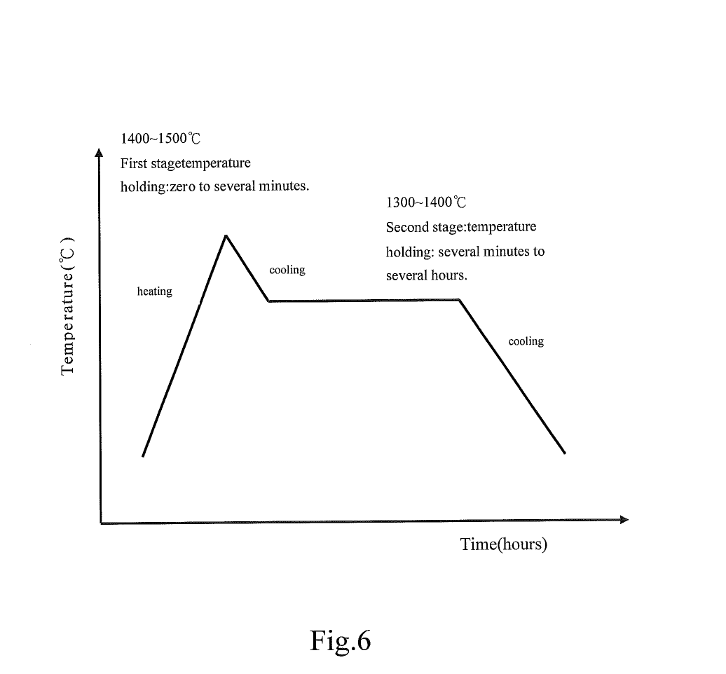

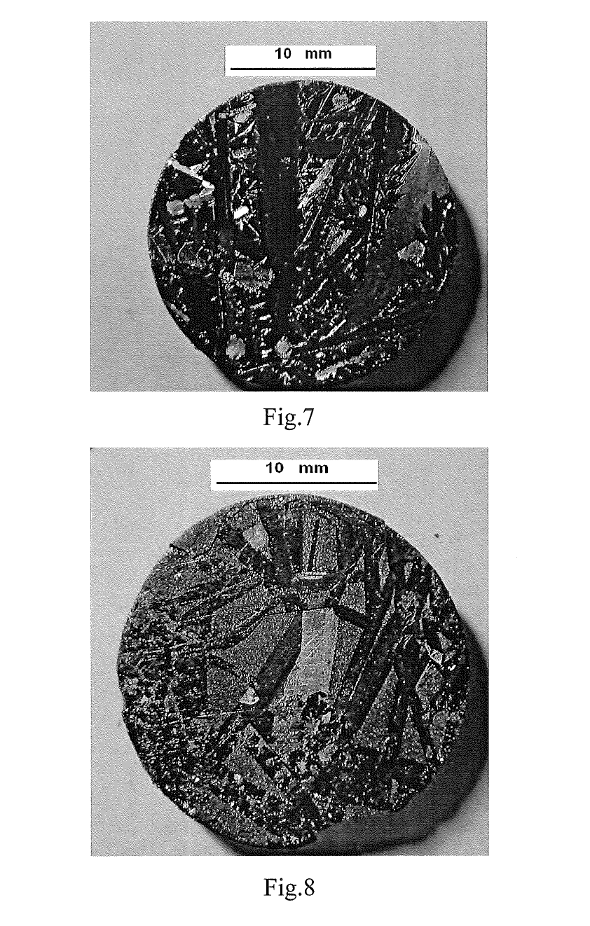

In this preferred embodiment of the present invention, we can observe the effect of the sintering conditions on the microstructure of a transition metal oxide doped barium titanate. The preferred embodiment produces a disc specimen according to the first embodiment, second embodiment and third embodiment of the present invention, wherein a two-stage sintering process is carried out (refer to the temperature-time profile as shown in FIG. 6). The specimen is put into a high-temperature furnace and sintered in a normal atmospheric pressure, and the sintering conditions include a temperature heating up with a rate of 3° C./min, no constant temperature maintaining when the temperature risen to a temperature range of 1400-1450° C. These steps constitute the first stage of the sintering process. The specimen is then cooled to a temperature range of 1300˜1400° C. at a cooling rate of 3° C./min, and then the temperature is maintained at the constant temperature for 2 hours, wherein those steps constitute the second stage of the sintering process. Finally, the specimen is cooled at a cooling rate of 3° C./min. From the microstructures of the barium titanate single crystals as shown in FIGS. 7 and 8, these figures show that the barium titanate single crystals can also be obtained by changing the sintering process from the one-stage heat treatment to the two-stages heat treatment.

To summarize the descriptions above, the present invention adds a small quantity of transition metal oxides into pure barium titanate ceramic powder, and then produces the barium titanate single crystal by a pressureless sintering process. The method in accordance with the preferred embodiments of the present invention is simple to be performed, and with its advantages, the method of the present invention is useful to industries. The usual price of the barium titanate single crystal is very high. But the barium titanate single crystals can be produced by using the economically competitive pressureless sintering technique in accordance with preferred embodiments of the present invention, and thus the recipe and manufacturing process of the invention is cost competitive. In addition, the barium titanate single crystals offer better ferroelectric property than that of the polycrystalline barium titanate. Without any grain boundary, the single crystals have a light transmitting capability and comes with a photorefractive nature, and thus the barium titanate single crystal can also be applied in the area of optical communications.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A barium titanate single crystal, containing a small quantity of metal oxide solid solution additive.

2. The barium titanate single crystal of claim 1, a crystalline phase is hexagonal.

3. The barium titanate single crystal of claim 1, wherein said metal oxide is a transition metal oxide.

4. The barium titanate single crystal of claim 3, wherein said transition metal oxide is either nickel oxide, iron oxide or their mixtures.

5. The barium titanate single crystal of claim 3, wherein said transition metal oxide has an initial content of 0.01% to 5% by weight.

6. The barium titanate single crystal of claim 3, wherein said transition metal oxide has an initial content of 0.01% to 2% by weight.

7. The barium titanate single crystal of claim 3, wherein said transition metal oxide has an initial content of 0.05% to 0.8% by weight.

8. A method of preparing barium titanate single crystal, comprising:
producing powder mixtures of barium titanate powder and metal oxide powders; and
performing a pressureless sintering process to prepare said barium titanate single crystal.

9. The method of claim 8, wherein said specimen is produced by the steps of: mixing a barium titanate powder, a metal oxide and a solvent to form a slurry;
removing said solvent to dry said powder;
sieving said dried powder after said powder is ground;
calcining the powder mixture in normal atmospheric pressure;
pressing said powder to form a specimen, after said powder is ground; and
sintering the specimen in normal atmospheric pressure.

10. The method of claim 8, wherein said metal oxide is in a form of oxide particles or metal salt particles.

11. The method of claim 9, wherein said metal oxide is in a form of oxide particles or metal salt particles.

12. The method of claim 9, wherein said solvent is an alcohol.

13. The method of claim 9, wherein said calcination conditions further comprise a temperature risen to 500° C., and a constant temperature maintaining for an hour, and a cooling process.

14. The method of claim 8, wherein said pressureless sintering method is a one-stage heat treatment that is carried out a sintering process at a normal atmospheric pressure, and the sintering conditions comprise a temperature risen to a temperature range from 1350° C. to 1500° C., a constant temperature maintaining for several minutes to several hours, and a cooling process.

15. The method of claim 9, wherein said pressureless sintering method is a one-stage heat treatment that carries out a sintering process at a normal atmospheric pressure, and the sintering conditions further comprise of a temperature risen to a temperature range from 1350° C. to 1500° C., a constant temperature maintaining for several minutes to several hours, and a cooling process.

16. The method of claim 8, wherein said pressureless sintering method is a two-stages heat treatment that carries out a sintering process at a normal atmospheric pressure, and the sintering conditions comprise: a temperature risen to a temperature range of 1400° C. to 1500° C., no constant temperature maintaining or a constant temperature maintaining for several minutes, a cooling process with a temperature range of 1300° C. to 1400° C., a constant temperature maintaining for several minutes to several hours, and a cooling.

17. The method of claim 9, wherein said pressureless sintering method is a two-stage heat treatment that carries out a sintering process at a normal atmospheric pressure, and the sintering conditions comprise a temperature risen to a temperature range of 1400° C. to 1500° C., no constant temperature maintaining or a constant temperature maintaining for several minutes, a cooling process with a temperature range of 1300° C. to 1400° C., a constant temperature maintaining for several minutes to several hours, and a cooling process.

18. A method of preparing barium titanate single crystal, comprising:
mixing barium titanate powder and metal oxides in a solvent to form a slurry;
removing said solvent in said slurry; and
performing a pressureless sintering process to said specimen to prepare said barium titanate single crystal.

19. The method of claim 18, further comprising:
removing said solvent of said slurry by a conventional drying method;
sieving said powder, after said dried powder is ground; and
forming said powder to form a specimen, after said powder mixture is ground.

20. The method of claim 19, wherein said metal oxide is added in the form of metal oxide particles or metal salt particles into said barium titanate powder.

21. The method of claim 18, wherein said metal oxide is in the form of metal oxide particles or metal salt particles into said barium titanate powder.

22. The method of claim 19, wherein said solvent is methanol, ethanol or isopropanol.

23. The method of claim 18, wherein said solvent is methanol, ethanol or isopropanol.

24. The method of claim 18, wherein said calcination conditions comprise a temperature risen to 500° C., a constant temperature maintaining for an hour, and a cooling process.

25. The method of claim 19, wherein said calcination conditions comprise a temperature risen to 500° C., a constant temperature maintaining for an hour, and a cooling process.

26. The method of claim 18, wherein said pressureless sintering method is one-stage heat treatment that is carried out at a normal atmospheric pressure, and the sintering conditions comprise a temperature risen with a temperature range of 1350° C. to 1500° C., a constant temperature maintaining for several minutes to several hours, and a cooling process.

27. The method of claim 19, wherein said pressureless sintering method is one-stage heat treatment that is carried out at a normal atmospheric pressure, and the sintering conditions comprise a temperature risen to a temperature range of 1350° C. to 1500° C., a constant temperature maintaining for several minutes to several hours, and a cooling process.

28. The method of claim 18, wherein said pressureless sintering method is a two-stage heat treatment that is carried out at a normal atmospheric pressure, and the sintering conditions comprise a temperature risen to a temperature range of 1400° C. to 1500° C., no constant temperature maintaining or a constant temperature maintaining for several minutes, a cooling process to a temperature range of 1300° C. to 1400° C., a constant temperature maintaining for several minutes to several hours, and a cooling process.

29. The method of claim 19, wherein said pressureless sintering method is a two-stages heat treatment that is carried out a sintering at a normal atmospheric pressure, and the sintering conditions comprise a temperature risen to a temperature range of 1400° C. to 1500° C., no constant temperature maintaining or a constant temperature maintaining for several minutes, a cooling process to a temperature range of 1300° C. to 1400° C., a constant temperature maintaining for several minutes to several hours, and a cooling process.
